(19) United States
(12) Patent Application Publication
(10) Pub. No.: US 2002/0040800 A1
(43) Pub. Date: Apr. 11, 2002

(54) Packaging structure of a chip

(76) Inventors: Da Sheng Lee, Taipei (TW); Ming Miao JR., Taoyuan Hsien (TW); Cheng-Ming Kuo, Taoyuan City (TW); Mei-Hui Chang, Keelung City (TW)

Correspondence Address: BACON & THOMAS, PLLC, 625 SLATERS LANE, FOURTH FLOOR, ALEXANDRIA, VA, 22314

(21) Appl. No.: 09/882,182

(22) Filed: Jun. 18, 2001

(30) Foreign Application Priority Data
Oct. 6, 2000 (TW) 089217407

(51) Int. Cl. H02G 3/08; H05K 5/00

(52) U.S. Cl. 174/52.1

(57) ABSTRACT

A packaging structure of a chip is disclosed. The packaging structure has high heat conductivity and a preferred electric insulation and can protect the chip. The packaging structure includes a chip, a lead frame, a signal transmission device for being connected to the chip and lead frame, a protecting gel layer, a diamond-like carbon layer, and an electric insulating layer. By aforesaid structure, when the chip is working, the heat from the chip is dissipated through the diamond-like carbon layer under the hollowed portion so that a working temperature of the chip is retained in a normal temperature.

### BACKGROUND OF THE INVENTION

1. Field of the Invention

The present invention relates to a packaging structure and, more particularly, to a packaging structure of a chip having a high conductivity and preferred electric insulation and capable of protecting the chip.

2. Description of Related Art

One of the most important processes in semiconductor manufacturing is to package a chip. While in the package process, stresses and heat dissipation are important considerations. In the aspect of improving heat dissipation, the conventional way includes to shorten heat transferring path, i.e., to reduce the thickness of the package. However, currently, the area of a chip is smaller and smaller, the way for resolving the aforesaid problems is to search for a material with a high conductivity and a preferred electric insulation and capable of protecting the chip.

The prior chip packaging structure or the method of the same may refer to Taiwan Patent No. 391,056, in that one surface of the chip is tightly sealed with a closed metal housing, and the interior thereof is installed with a capillary structure and heat exchanging fluids for heat dissipation. Furthermore, U.S. Pat. No. 5,696,665 discloses a substrate combined to two surfaces of a crystal. The surface of the substrate is covered with a thin diamond film having a high heat conductivity and high electric insulation. The former has a complex structure and extra combining processes are necessary, and the latter uses preferred material, but the heat dissipation effect of the substrate is not good enough.

Therefore, it is desirable to provide an improved packaging structure of a chip to mitigate and/or obviate the aforementioned problems.

### SUMMARY OF THE INVENTION

The object of the present invention is to provide a packaging structure of a chip having a high heat conductivity and preferred electric insulation and can protect the chip.

To achieve the above object, the present invention provides a packaging structure of a chip, which comprises a chip, a lead frame, a protecting gel layer, a diamond-like carbon layer and an electric insulating layer. The chip includes a front surface and a back surface. The lead frame is connected to the chip through a signal transmission device. The protecting gel layer covers on the signal transmission device. The diamond-like carbon layer covers on the front surface and back surface of the chip. The electric insulating layer covers on the protecting gel layer and/or the diamond-like carbon layer and being formed with an hollowed portion. According to the aforesaid structure, when the chip is working, the heat from the chip is dissipated through the hollowed portion of the diamond-like carbon layer so that a working temperature of the chip is retained in a normal temperature.

Other objects, advantages, and novel features of the invention will become more apparent from the following detailed description when taken in conjunction with the accompanying drawings.

### BRIEF DESCRIPTION OF THE DRAWINGS

FIG. 1 is a perspective view of the first embodiment in the present invention.

FIG. 2 is a cross sectional view of the first embodiment of the present invention.

FIG. 3 is a cross sectional view of the second embodiment in the present invention.

FIG. 4 is a cross sectional view of the third embodiment of the present invention.

### DETAILED DESCRIPTION OF THE PREFERRED EMBODIMENT

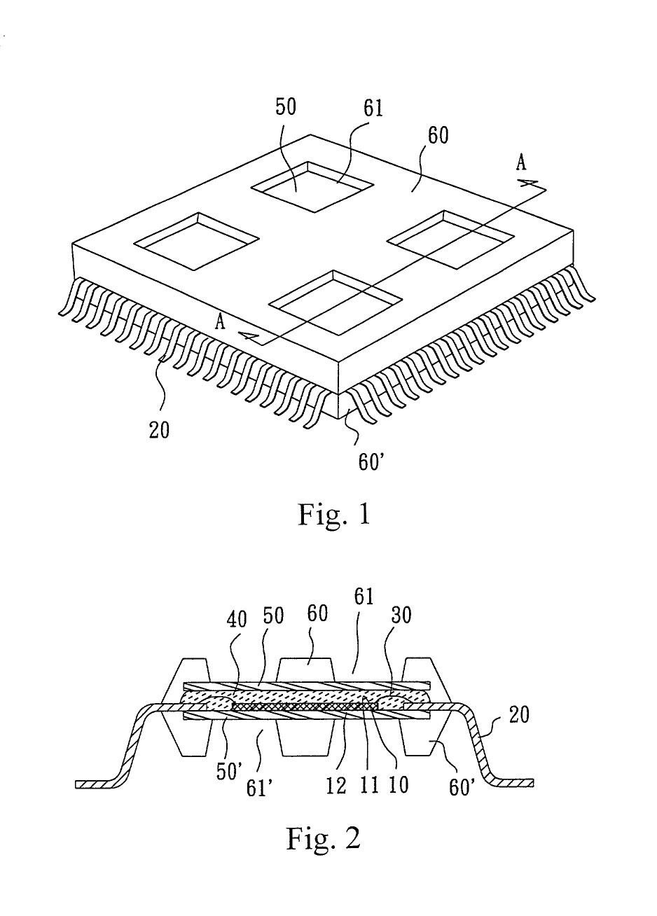

With reference to FIGS. 1 and 2, a perspective view and cross sectional view of the novel packaging structure of a chip according to the present invention are illustrated. The packaging structure includes a chip 10, a lead frame 20, a protecting gel layer 40, two diamond-like carbon layers 50, 50′, two epoxy layers 60, 60′, and hollowed portions 61, 61′. The chip 10 has a front surface 11 and a back surface 12. The lead frame 20 is connected to the chip 10 through a gold wire 30. The protecting gel layer 40 covers on the front surface 11 of the chip 10. The two diamond-like carbon layers 50, 50′ covers on the protecting gel layer 40 and the back surface 12 of the chip 10. The two epoxy layers 60, 60′ covers on the diamond-like carbon layers 50, 50′. The hollowed portions 61, 61′ are formed as a cross on the diamond-like carbon layers 50, 50′.

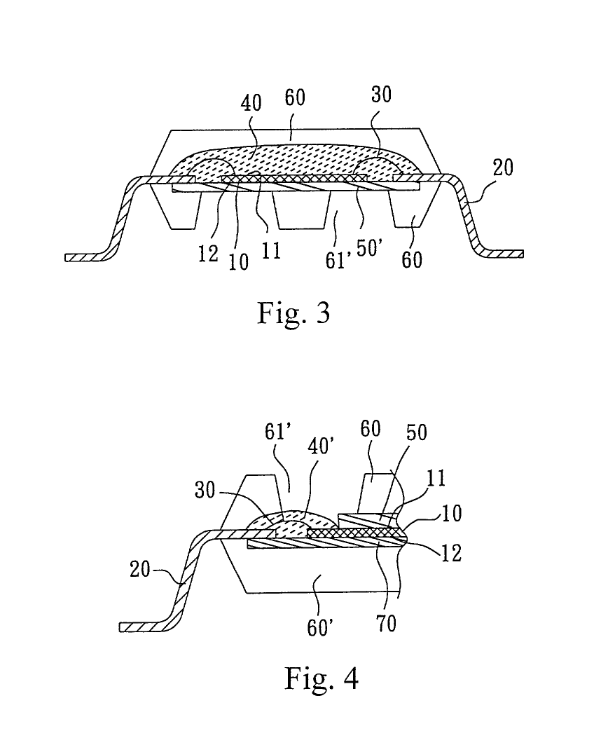

FIG. 3 is a cross sectional view of the second embodiment of the packaging structure of a chip according to the present invention The difference of this embodiment from the aforesaid embodiment is that a epoxy layer 60 is directly covered on the protecting gel layer 40 at the front surface of the chip without any hollowed portion.

FIG. 4 is a cross sectional view of the second embodiment of the packaging structure of a chip according to the present invention. The difference of this embodiment from the first embodiment is that the protecting gel layer 40′ only covers on the gold wire 30, the diamond-like carbon layer 50 directly covers on the front surface 11 of the chip. Additionally, the back surface 12 of the chip 10 is tightly combined with a copper substrate 70. The diamond-like carbon layer 50 and the copper substrate 70 are covered by the epoxy layer 60, 60′ and only a hollowed portions 61 in the shape of a cross on the diamond-like carbon layers 50 is formed.

According to the aforesaid structures, most surfaces of the diamond-like carbon layers 50, 50′ can directly contact with the environment. Since the diamond-like carbon has superior heat conductivity and electric insulation, the heat from a working chip can be dissipated and thus the working temperature of the chip retains normally. The shape of the hollowed portion is not confined, and can be modified for enhancing the structure strength without impact on heat dissipation.

Although the present invention has been explained in relation to its preferred embodiment, it is to be understood that many other possible modifications and variations can be made without departing from the spirit and scope of the invention as hereinafter claimed.

What is claimed is:

1. A packaging structure of a chip comprising:
a chip including a front surface and a back surface;
a lead frame being connected to said chip through a signal transmission device;
a protecting gel layer covering on said signal transmission device;
a diamond-like carbon layer covering on said front surface and/or said back surface of said chip; and
an electric insulating layer covering on said protecting gel layer and/or said diamond-like carbon layer, and being formed with an hollowed portion;
according to aforesaid structure, when said chip is working, the heat from said chip is dissipated through said diamond-like carbon layer under said hollowed portion so that a working temperature of said chip is retained in a normal temperature.

2. The packaging structure of a chip as claimed in claim 1, wherein said electric insulating layer is made of epoxy.

3. The packaging structure of a chip as claimed in claim 1, wherein said signal transmission device is a gold wire.
